(19) United States
(12) Patent Application Publication
(10) Pub. No.: US 2021/0256761 A1
(43) Pub. Date: Aug. 19, 2021

(54) SYSTEMS AND METHODS FOR GENERATING 2D TRAINING IMAGES FROM 3D DESIGN IMAGES

(71) Applicant: SIGNIFY HOLDING B.V., EINDHOVEN (NL)

(72) Inventors: Shahin MAHDIZADEHAGHDAM, CAMBRIDGE, MA (US); Daksha YADAV, CAMBRIDGE, MA (US); Olaitan Philip OLALEYE, CAMBRIDGE, MA (US); Arhum SAVERA, CAMBRIDGE, MA (US); Yizhou ZANG, CAMBRIDGE, MA (US)

(21) Appl. No.: 17/173,711

(22) Filed: Feb. 11, 2021

Related U.S. Application Data
(60) Provisional application No. 62/977,551, filed on Feb. 17, 2020.

(30) Foreign Application Priority Data
Feb. 27, 2020 (EP) 20159657.4

(51) Int. Cl. G06T 15/20; G06T 15/50; G06N 3/04; G06T 7/73; G06F 30/27; G06F 30/23

(52) U.S. Cl. CPC G06T 15/205; G06T 15/506; G06N 3/04; G06T 2207/20084; G06F 30/27; G06F 30/23; G06T 7/73

(57) ABSTRACT

A system for generating two-dimensional images is provided. The system may include a controller configured to receive a three-dimensional design image. The controller may be further configured to generate a fake 2D image based on the 3D design image and one or more 3D image parameters, such as object orientation. The controller may be further configured to generate a realistic 2D image based on the fake 2D image and one or more image features. The controller may be further configured to evaluate a realism value of the realistic 2D image based on one or more real 2D images. The controller may be further configured to evaluate a detected orientation of the realistic 2D image. The controller may be further configured to update the realistic image generator based on the realism value or the detected orientation.

### CROSS-REFERENCE TO PRIOR APPLICATIONS

This application claims the benefits of European Patent Application No. 20159657.4, filed on Feb. 27, 2020 and United States Patent Application No. 62/977551, filed on Feb. 17, 2020. These applications are hereby incorporated by reference herein.

### FIELD OF THE DISCLOSURE

The present disclosure is directed generally to generating two-dimensional training images from three-dimensional design images.

### BACKGROUND

Training deep learning algorithms requires an enormous amount of data. For example, properly training a reliable image classifier or object detector may require a training dataset of hundreds of thousands, or even millions, of images from each class of image or object. This requirement may be further intensified when training deeper models. Gathering this amount of data organically is often expensive and time-consuming.

Generative Adversarial Networks (GANs) have demonstrated great potential to generate synthetic images. GANs may be used as a data augmentation technique, and the images generated by the GANs may be added to a training dataset. However, images typically generated via GANs are insufficiently realistic to significantly improve the classification and/or detection accuracy of a deep learning algorithm.

As an alternative approach to generating synthetic images for training purposes, three-dimensional (3D) design images may be rendered to generate two-dimensional (2D) images according to various poses, scales, and colors. However, the 2D images derived from a 3D image often lack the requisite level of detail of real images needed for classification and/or detection purposes. Accordingly, there is a need for systems and methods for generating a high volume of realistic 2D images for deep learning training.

### SUMMARY OF THE DISCLOSURE

The present disclosure is directed to generating two-dimensional (2D) images from three-dimensional (3D) design images by combining a 3D rendering engine with a Generative Adversarial Network (GAN). The 3D rendering engine may generate fake 2D images with a given orientation, scale, rotation, and/or color. The GAN may then transform the fake 2D images into realistic-looking images by editing the image and adding necessary components and lighting effects. A discriminator is then employed to evaluate the realism and orientation of the realistic-looking image. The GAN is subsequently updated and improved based on this evaluation of the realistic-looking image.

Generally, in one aspect, a controller for generating 2D images is provided. The controller may be configured to receive a 3D design image. The 3D design image may be a 3D Computer Aided Design (“CAD”) file. The 3D design image may include a 3D lightbulb design.

The controller may be further configured to generate, via a 3D rendering engine , a fake 2D image based on the 3D design image and one or more 3D image parameters. According to an example, one of the 3D image parameters may be an object orientation, an object color, or an illumination value.

The controller may be further configured to generate, via a realistic image generator of a Generative Adversarial Network (“GAN”), a realistic 2D image based on the fake 2D image and one or more image features. According to an example, one of the image features may be an image illumination value, an obstruction image, or a background image.

The controller may be further configured to evaluate, via a discriminator of the GAN, a realism value of the realistic 2D image based on one or more real 2D images. The real 2D images may include one or more photographs. The controller may be further configured to update the realistic image generator based on the realism value of the realistic 2D image.

According to an example, the controller may be further configured to evaluate, via a discriminator, a detected orientation of the realistic 2D image. The controller may be further configured to update the realistic image generator based on the detected orientation. The controller may be further configured to generate an orientation classification based on the detected orientation. The fake 2D images may be generated further based on the orientation classification.

According to an example, the GAN may be defined by the equation:

$${min}_{G} {max}_{{D}_{r} , {D}_{o}} V ( {D}_{r} , {D}_{o} , G ) = {𝔼}_{x \sim {p}_{d a t a} ( x )} [ log ( {D}_{r} ( x ) ) ] + {𝔼}_{y \sim {p}_{y} ( y )} [ log ( 1 - {D}_{r} ( G ( y ) ) ) ] - {𝔼}_{y \sim {p}_{y} ( y )} [ MSE ( {D}_{o} ( y ) , {o}_{y} ) ]$$

Generally, in another aspect, a method for generating 2D images is provided. The method may include receiving a 3D design image. The method may further include generating, via a 3D rendering engine, a fake 2D image based on the 3D design image and one or more 3D image parameters. According to an example, one of the 3D image parameters is object orientation. The method may further include generating, via a realistic image generator, a realistic 2D image based on the fake 2D image and one or more image features.

According to an example, the method may further include evaluating, via a discriminator, a realism value of the realistic 2D image based on one or more real 2D images. The method may further include updating the realistic image generator based on the realism value of the realistic 2D image.

According to an example, the method may further include evaluating, via a discriminator, a detected orientation of the realistic 2D image based on one or more real 2D images and the object orientation. The method may further include updating the realistic image generator based on the detected orientation of the realistic 2D image.

In various implementations, a processor or controller may be associated with one or more storage media (generically referred to herein as “memory,” e.g., volatile and non-volatile computer memory such as RAM, PROM, EPROM, and EEPROM, floppy disks, compact disks, optical disks, magnetic tape, etc.). In some implementations, the storage media may be encoded with one or more programs that, when executed on one or more processors and/or controllers, perform at least some of the functions discussed herein. Various storage media may be fixed within a processor or controller or may be transportable, such that the one or more programs stored thereon can be loaded into a processor or controller so as to implement various aspects as discussed herein. The terms “program” or “computer program” are used herein in a generic sense to refer to any type of computer code (e.g., software or microcode) that can be employed to program one or more processors or controllers.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

These and other aspects of the various embodiments will be apparent from and elucidated with reference to the embodiment(s) described hereinafter.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the various embodiments.

FIG. 1 is a flowchart depicting the data processes of a controller for generating 2D images, in accordance with an example.

FIG. 2 is a pair of images showing the transformation of a fake 2D image to a realistic 2D image.

FIG. 3 is a first flowchart of a method for generating 2D images, in accordance with an example.

FIG. 4 is a second flowchart of a method for generating 2D images, in accordance with an example.

### DETAILED DESCRIPTION OF EMBODIMENTS

The present disclosure is directed to generating two-dimensional (2D) images from three-dimensional (3D) design images by combining a 3D rendering engine with a Generative Adversarial Network (GAN). The 3D rendering engine generates fake 2D images with a given orientation, scale, rotation, and/or color. The GAN then transforms the fake 2D images into realistic-looking images by editing the image and adding necessary components and lighting effects. A discriminator is then employed to evaluate the realism and detected orientation of the realistic-looking image. The GAN is subsequently updated and improved based on this evaluation of the realistic-looking image. Accordingly, the disclosed systems and methods may be used to generate a high volume of realistic-looking images used to train deep learning algorithms. Further, by updating the GAN with the detected orientations of the realistic 2D images, the realistic images with common orientation may be similarly transformed for improved image consistency. Generating a high volume of commonly oriented realistic-looking images allows for greater precision in deep learning algorithm training.

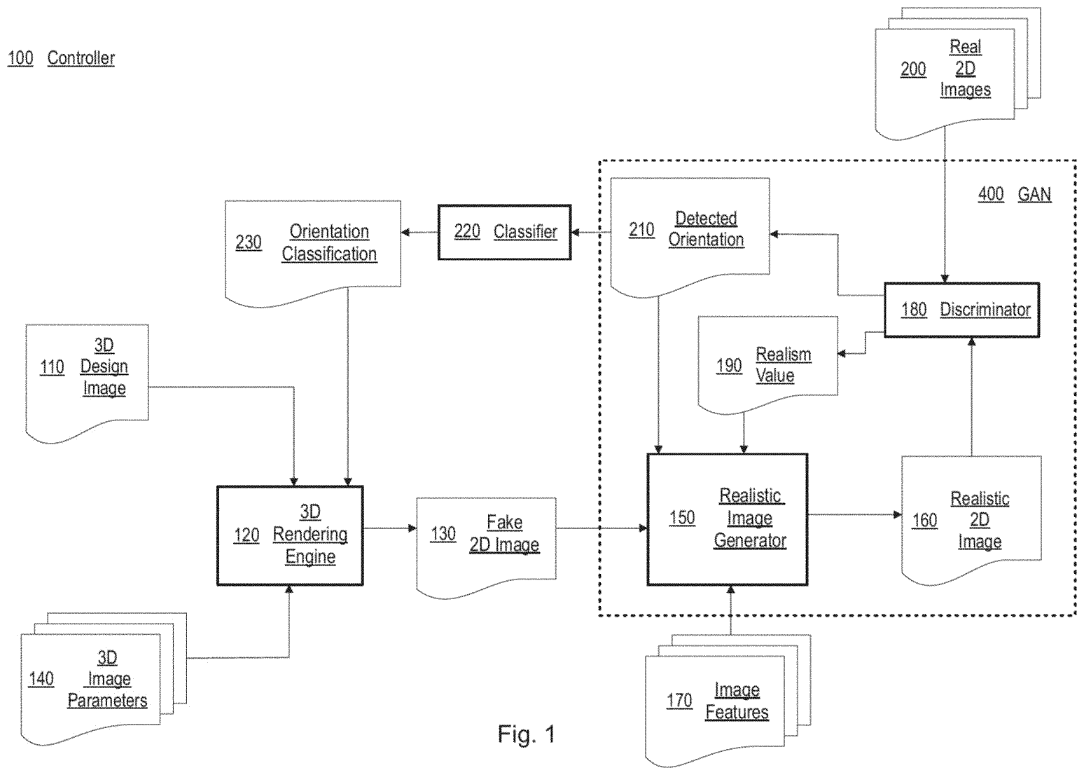

In one aspect of the present disclosure, a controller 100 for generating 2D images is provided. The flow of data with respect to the controller 100 is shown in FIG. 1. The generated 2D images may be used to train a deep learning algorithm. The controller 100 may be configured to generate a high volume of images, such as, for example, several hundred thousand images.

The controller 100 may be configured to receive a 3D design image 110. In one example, the 3D design image 110 may be a 3D Computer-Aided Design (CAD) file. In further examples, the 3D design image 110 may be any 3D representation of a 3D object. In a preferred embodiment, the 3D design image 110 may include a 3D lightbulb design.

The controller 100 may receive the 3D design image 110 through any practical means, such as wired or wireless transmission. Upon receiving the 3D design image 110, the controller 100 may store the image in a memory.

The controller 100 may be further configured to generate, via a 3D rendering engine 120, a fake 2D image 130 based on the 3D design image 110 and one or more 3D image parameters 140. According to an example, one of the 3D image parameters 140 may be object orientation. The object orientation refers to the rotation and/or alignment of the 3D object depicted by the 3D design image 110. In other examples, one of the 3D image parameters 140 may be object scale (referring to the size of the 3D object relative to the 3D design image 110) or object color. Multiple 3D image parameters 140 may be applied simultaneously. For example, the 3D image parameters 140 may set the object orientation of the 3D object to a 90-degree rotation, and also set the color of the 3D object to be red.

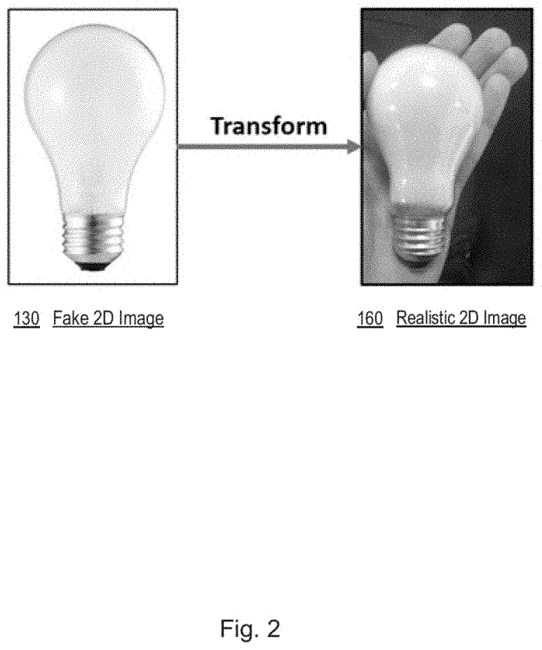

An example fake 2D image 130 is shown on the left side of FIG. 2. As can be seen in FIG. 2, the fake 2D image 130 appears to be a synthetic, 2D reproduction of an image of a lightbulb. While similar to a realistic image, the fake 2D image lacks many of the elements and qualities of a real photograph of a lightbulb. Subsequent steps performed by the components of GAN 400, namely, realistic image generator 150, incorporate additional elements into the image to create a realistic 2D image 160.

Generally, GANs have been previously used to synthesize images from random low dimensional outputs. In the present application, an existing GAN has been modified to transform the fake 2D image 130 of, for example, a lightbulb, into a realistic 2D image 160. In this synthesis, the GAN 400 may transform the fake 2D image 130 in one or more ways to make it look more realistic, such as incorporating a hand holding and/or covering some portion of the lightbulb, or applying one or more different backgrounds to the fake 2D image 130.

As stated above, the GAN 400 is responsible for transforming fake 2D images 130 into realistic 2D images 160. The architecture of the GAN 400 is an encoder-decoder similar to a Feature Pyramid Network. A Feature Pyramid Network is a pyramid of features designed for image classification or object detection applications. Feature Pyramid Networks employ feature networks to extract information regarding features of the images processed.

The controller 100 may be further configured to generate, via a realistic image generator 150, a realistic 2D image 160 based on the fake 2D image 130 and one or more image features 170. As shown in FIG. 1, the realistic image generator 150 is a component of GAN 400. According to an example, one of the image features 170 may be an image illumination value. The image illumination value may set the brightness level of at least a portion of the image. According to a further example, one of the image features 170 is an obstruction image. As shown on the right side of FIG. 2, the obstruction may be a portion of a hand partially obscuring the fake 2D image 130 of a lightbulb. According to a further example, one of the image features 170 may be a background image. The background image may be a lighting fixture into which the lightbulb represented by the fake 2D image 130 may be installed. The realistic image generator 150 may use multiple image features 170 to generate the realistic 2D image 160.

The realistic 2D images 160 generated by the realistic image generator 150 of the GAN 400 may be sufficient to train deep learning algorithms. However, the quality of the realistic 2D images 160 may be improved by feedback generated by a discriminator 180 of the GAN 400.

According to an example, the controller 100 may be further configured to evaluate, via a discriminator 180, a realism value 190 of the realistic 2D image 160 based on one or more real 2D images 200. The real 2D images 200 may be an array of actual photographs of lightbulbs stored in memory. The realism value 190 may increase or decrease according to the similarities or differences of the realistic 2D image 160 as compared to the real 2D images 200. The controller 100 may be further configured to update the realistic image generator 150 based on the realism value 190 of the realistic 2D image 160. For example, based on the realism value 190, the realistic image generator may modify the parameters of the one or more image features 170 incorporated into the fake 2D image 130 to generate the realistic 2D image 160.

Similarly, according to a further example, the controller 100 may be further configured to evaluate, via the discriminator 180, a detected orientation 210 of the realistic 2D image 160. The controller 100 may be further configured to update the realistic image generator 150 based on the detected orientation 210 of the realistic 2D image 160.

The controller 100 may be further configured to generate, via a classifier 220, an orientation classification 230 based on the detected orientation 210. In a further example, the fake 2D images 130 are generated further based on the orientation classification 230. As a result, all realistic 2D images 160 subsequently generated by the controller 100 will have an orientation within the orientation classification 230. In another example, the detected orientation 210 may train the realistic image generator 150 to transform similarly oriented images in a similar manner. Further explanation regarding the GAN 400 and discriminator 180 may be found below.

As described above, the discriminator 180 may evaluate both the realism of the realistic 2D image 160, as well as detect the orientation (the viewing angle, distance to the bulb, etc.) of the image 160. The realism value 190 may be a binary value corresponding to whether the image 160 appears to be real or fake (i.e., synthetic or computer generated). The GAN 400 may be formalized as follows:

$${min}_{G} {max}_{{D}_{r} , {D}_{o}} V ( {D}_{r} , {D}_{o} , G ) = {𝔼}_{x \sim {P}_{data} ( x )} [ log ( {D}_{r} ( x ) ) ] + {𝔼}_{y \sim {p}_{y} ( y )} [ log ( 1 - {D}_{r} ( G ( y ) ) ) ] - {𝔼}_{y \sim {p}_{y} ( y )} [ MSE ( {D}_{o} ( y ) , {o}_{y} ) ] \qquad ( 1 )$$

where G, Dᵣ, Dₒ are the generator 150, discriminator 180 detecting if the bulb is real or fake, and the discriminator 180 detecting the correct orientation of the bulb in the image. p_{data} and p_{y} are the distributions of the real images 200 and the generated images 160 respectively. The “−MSE(Dₒ(y), o_{y})” term was added to equation 1 to determine the Mean Square Error (MSE) between the detected orientation 210 of the image (such as a lightbulb) and the ground truth orientation of the bulb in the image 160. The ground truth orientation of the image 160 may correspond to the object orientation 230 of the 3D design image 110 used by the 3D rendering engine 120 to generate the fake 2D image 130.

The first term in the right-hand side of equation 1, log(Dᵣ(x)), ensures the discriminator 180 assigns larger values to the “real” images. The goal of the second term, log(1−Dᵣ(G(y))), is to make sure that the discriminator 180 assigns smaller values to “fake” images. Also, the generated images 160 which appear to be more “real” than “fake” will be assigned larger values. The third term, as discussed previously, allows the discriminator 180 to detect the orientation of the image 160, such as, the orientation of a lightbulb found in the image 160.

Training the discriminator 180 to identify the orientation of the bulbs helps the realistic image generator 150 to similarly transform the fake 2D images 130 within the same orientation classification 230. In other words, the realistic image generator 150 will not change the orientation of the fake 2D image 130, but it will only add relevant image features 170 (such as a hand holding the bulb, or an object covering some part of the bulb) and background images to the realistic 2D image 160. Generating images of bulbs with various background images allows deep learning algorithms to be independent of backgrounds in classifying the bulb images.

Restricting the realistic image generator 150 to only transform fake 2D images 130 with similar orientations may produce more realistic 2D images 160 with higher realism values 190. Additionally, since the orientations 210 of the images 160 are identified by the discriminator 180, this approach helps to avoid the notorious mode collapse problem of conventional GANs in which a generator network is only capable of producing images from a limited variety.

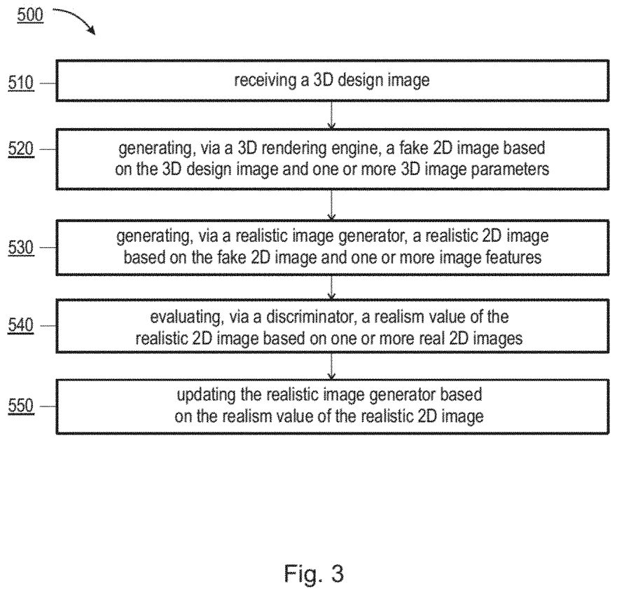

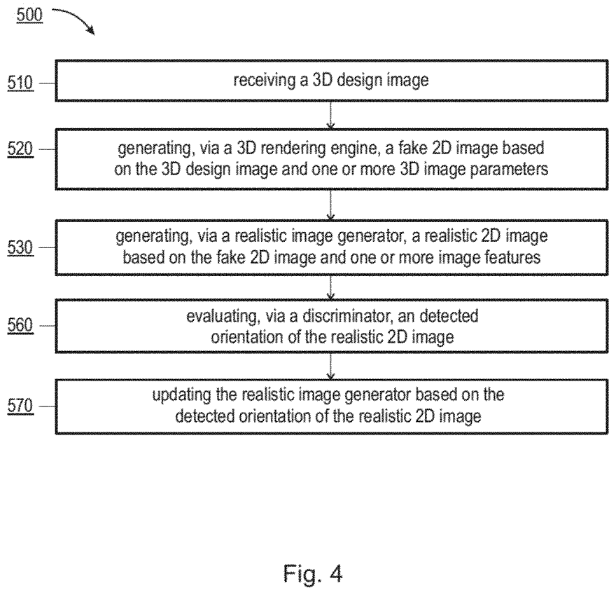

Referring to FIGS. 3 and 4, in another aspect, a method 500 for generating 2D images is provided. The method 500 may include receiving 510 a 3D design image. The method 500 may further include generating 520, via a 3D rendering engine, a fake 2D image based on the 3D design image and one or more 3D image parameters. According to an example, one of the 3D image parameters may be object orientation. The method 500 may further include generating 530, via a realistic image generator, a realistic 2D image based on the fake 2D image and one or more image features.

According to an example, the method 500 may further include evaluating 540, via a discriminator, a realism value of the realistic 2D image based on one or more real 2D images. The method 500 may further include updating 550 the realistic image generator based on the realism value of the realistic 2D image.

According to an example, the method 500 may further include evaluating 560, via a discriminator, a detected orientation of the realistic 2D image. The method may further include updating 570 the realistic image generator based on the detected orientation.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of” or “exactly one of.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The above-described examples of the described subject matter can be implemented in any of numerous ways. For example, some examples may be implemented using hardware, software or a combination thereof. When any aspect of an example is implemented at least in part in software, the software code can be executed on any suitable processor or collection of processors, whether provided in a single device or computer or distributed among multiple devices/computers.

The present disclosure may be implemented as a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some examples, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to examples of the disclosure. It will be understood that each block of the flowchart illustrations and/or block diagrams, and combinations of blocks in the flowchart illustrations and/or block diagrams, can be implemented by computer readable program instructions.

The computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various examples of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

What is claimed is:

1. A controller for generating 2D images, the controller configured to:
receive a 3D design image;
generate, via a 3D rendering engine, a fake 2D image based on the 3D design image and one or more 3D image parameters;
generate, via a realistic image generator of a Generative Adversarial Network (“GAN”), a realistic 2D image based on the fake 2D image and one or more image features;
evaluate, via a discriminator of the GAN, a realism value of the realistic 2D image based on one or more real 2D images; and
update the realistic image generator based on the realism value of the realistic 2D image.

2. The controller of claim 1, wherein the controller is further configured to evaluate, via a discriminator, a detected orientation of the realistic 2D image.

3. The controller of claim 2, wherein the controller is further configured to update the realistic image generator based on the detected orientation.

4. The controller of claim 3, wherein the controller is further configured to generate, via a classifier, an orientation classification based on the detected orientation.

5. The controller of claim 4, wherein the fake 2D images are generated further based on the orientation classification.

6. The controller (100) of claim 1, wherein the GAN (400) is defined by the equation:
$${min}_{G} {max}_{{D}_{r} , {D}_{o}} V ( {D}_{r} , {D}_{o} , G ) = {𝔼}_{x \sim {P}_{data} ( x )} [ log ( {D}_{r} ( x ) ) ] + {𝔼}_{y \sim {p}_{y} ( y )} [ log ( 1 - {D}_{r} ( G ( y ) ) ) ] - {𝔼}_{y \sim {p}_{y} ( y )} [ MSE ( {D}_{o} ( y ) , {o}_{y} ) ]$$

7. The controller of claim 1, wherein the 3D design image is a 3D Computer Aided Design (“CAD”) file.

8. The controller of claim 1, wherein one of the 3D image parameters is either an object orientation, an object color, or an illumination value.

9. The controller of claim 1, wherein one of the image features is either an image illumination value, an obstruction image, or a background image.

10. The controller of claim 1, wherein the 3D design image comprises a 3D lightbulb design.

11. The controller of claim 1, wherein the one or more real 2D images comprise one or more photographs.

12. A method for generating 2D images, comprising:
receiving a 3D design image;
generating, via a 3D rendering engine, a fake 2D image based on the 3D design image and one or more 3D image parameters;
generating, via a realistic image generator of a Generative Adversarial Network (“GAN”), a realistic 2D image based on the fake 2D image and one or more image features;
evaluating, via a discriminator of the GAN, a realism value of the realistic 2D image based on one or more real 2D images; and
updating the realistic image generator based on the realism value of the realistic 2D image.

13. The method of claim 12, wherein the GAN is defined by the equation:
$${min}_{G} {max}_{{D}_{r} , {D}_{o}} V ( {D}_{r} , {D}_{o} , G ) = {𝔼}_{x \sim {P}_{data} ( x )} [ log ( {D}_{r} ( x ) ) ] + {𝔼}_{y \sim {p}_{y} ( y )} [ log ( 1 - {D}_{r} ( G ( y ) ) ) ] - {𝔼}_{y \sim {p}_{y} ( y )} [ MSE ( {D}_{o} ( y ) , {o}_{y} ) ]$$

14. The method of claim 12, wherein one of the 3D image parameters is object orientation.

15. The method of claim 14, further comprising:
evaluating, via a discriminator, a detected orientation of the realistic 2D image; and
updating the realistic image generator based on the detected orientation.
